(19) United States
(12) Patent Application Publication
(10) Pub. No.: US 2026/0096487 A1
(43) Pub. Date: Apr. 2, 2026

(54) SEMICONDUCTOR DIE STACKS USING DIRECT BONDS

(71) Applicant: Micron Technology, Inc., Boise, ID (US)

(72) Inventors: Youngrae KIM, Taichung (TW); Sui Chi HUANG, Taichung (TW); Youngik KWON, Taichung (TW)

(21) Appl. No.: 19/292,077

(22) Filed: Aug. 6, 2025

Related U.S. Application Data
(60) Provisional application No. 63/702,197, filed on Oct. 2, 2024.

(51) Int. Cl. H01L 25/065; H01L 21/56; H01L 23/00; H10B 80/00

(52) U.S. Cl. CPC H10W 90/00; H10B 80/00; H10W 74/016; H10W 72/01255; H10W 72/227; H10W 80/312; H10W 80/327; H10W 90/724; H10W 90/792

(57) ABSTRACT

Implementations described herein relate to various semiconductor device assemblies. In some implementations, a semiconductor device assembly includes: a substrate; a stack of one or more semiconductor dies, the one or more semiconductor dies including a first semiconductor die directly bonded to a second semiconductor die; and one or more conductive pillars that electrically couple respective semiconductor dies of the one or more semiconductor dies with the substrate.

### CROSS-REFERENCE TO RELATED APPLICATION

This patent application claims priority to U.S. Provisional Patent Application No. 63/702,197, filed on Oct. 2, 2024, entitled “SEMICONDUCTOR DIE STACKS USING DIRECT BONDS,” and assigned to the assignee hereof. The disclosure of the prior application is considered part of and is incorporated by reference into this patent application.

### TECHNICAL FIELD

The present disclosure generally relates to semiconductor devices and methods of forming semiconductor devices. For example, the present disclosure relates to semiconductor die stacks using direct bonds.

### BACKGROUND

A semiconductor package may include a semiconductor substrate, one or more semiconductor electronic components coupled to and/or embedded in the semiconductor substrate, and a casing formed over the semiconductor substrate to encapsulate the one or more semiconductor electronic components. The one or more semiconductor electronic components may be interconnected by electrical interconnects to form one or more semiconductor devices, such as one or more integrated circuits (ICs) (e.g., one or more dies or chips). For example, the semiconductor electronic components and the electrical interconnects may be fabricated on a semiconductor wafer to form one or more ICs before being diced into dies or chips and then packaged. A semiconductor package may be referred to as a semiconductor chip package that includes one or more ICs. A semiconductor package protects the semiconductor electronic components and the electrical interconnects from damage and includes a mechanism for connecting the semiconductor electronic components and the electrical interconnects to external components (e.g., a circuit substrate), such as via balls, pins, leads, contact pads, or other electrical interconnect structures. A semiconductor device assembly may be or may include a semiconductor package, multiple semiconductor packages, and/or one or more components of a semiconductor package (e.g., one or more semiconductor devices with or without a casing).

An electronic system assembly may include multiple semiconductor packages electrically coupled to a carrier substrate (e.g., circuit substrate). An electronic system assembly may include additional system components electrically coupled to the carrier substrate. The carrier substrate may include electrical interconnects and conductive paths used for interconnecting system components, including the multiple semiconductor packages and other system components of the electronic system assembly. Accordingly, the multiple semiconductor packages may be electrically connected to each other and/or to one or more additional system components via the carrier substrate to form the electronic system assembly. By way of example, other system components may include passive components (e.g., storage capacitors), processing units (e.g., a central processing unit (CPU), a graphics processing unit (GPU), a microprocessor, and/or a microcontroller), control units (e.g., a microcontroller, a memory controller, and/or a power management controller), or one or more other electronic components.

### BRIEF DESCRIPTION OF THE DRAWINGS

FIG. 1 is a diagram of an example apparatus that may be manufactured using techniques described herein.

FIG. 2 is a diagram of an example memory device that may be manufactured using techniques described herein.

FIG. 3 is a diagram of an example apparatus that supports semiconductor die stacks using direct bonds.

FIG. 4A through FIG. 4M are diagrammatic views showing a process that supports semiconductor die stacks using direct bonds

FIG. 5 is a flowchart of an example method of forming an integrated assembly or memory device having semiconductor die stacks using direct bonds.

### DETAILED DESCRIPTION

Some semiconductor device packages may include one or more stacks of semiconductor dies disposed over a substrate. In some cases, such stacks may include die attach film (DAF) material to bond together adjacent semiconductor dies. Using DAF material may provide mechanical stability during the manufacturing process. Further, DAF material may enable wire bonding to electrically couple a semiconductor die (e.g., an electronic interface of the semiconductor die) to one or more contacts of the substrate. For example, and as described in greater detail elsewhere herein, the substrate may include or may be an example of a redistribution layer that includes

However, DAF material used to bond semiconductor dies may contribute significantly to the overall height of the semiconductor device package without contributing to the performance of the semiconductor device. For example, if the semiconductor device includes a memory system, the increased height added by the DAF material may reduce the memory density of the memory system. Furthermore, in some examples, wire bond routing used to electrically couple the semiconductor dies to the substrate may introduce complexities in the manufacturing process.

Some implementations described herein provide a semiconductor package that enables direct bonding between semiconductor dies. For example, a shingled stack of one or more semiconductor dies may be joined together using a direct bond (e.g., by directly bonding semiconductor dies). Directly bonding semiconductor dies may include joining the semiconductor dies without using a DAF material between the semiconductor dies, such as by forming a fusion bond between surfaces of semiconductor dies. For example, directly bonding a first semiconductor die to a second semiconductor die may include forming a fusion bond between an upper surface of the first semiconductor die to a lower surface of the second semiconductor die.

In some examples, a semiconductor die may have one or more slanted sidewalls. A slanted sidewall may extend in a vertical direction and in a horizontal direction. Slanted sidewalls of a semiconductor die may be arranged such that the semiconductor die has a trapezoidal shape. Said another way, slanted sidewalls of a semiconductor die may be oriented such that a width of an upper surface of the semiconductor die may be greater than a width of a lower surface of the semiconductor die.

As a result, by forming stacks of semiconductor dies using direct bonds, the overall size of the semiconductor package may be reduced. For example, by using direct bonds, the mechanical stability of the stack of semiconductor dies may be improved without including DAF material between semiconductor dies. Accordingly, the height of a semiconductor package may be reduced, which may result in a reduced package profile. Furthermore, direct bonding may improve thermal conductivity between semiconductor dies, which may improve heat dissipation and thus improve thermal management of the semiconductor dies.

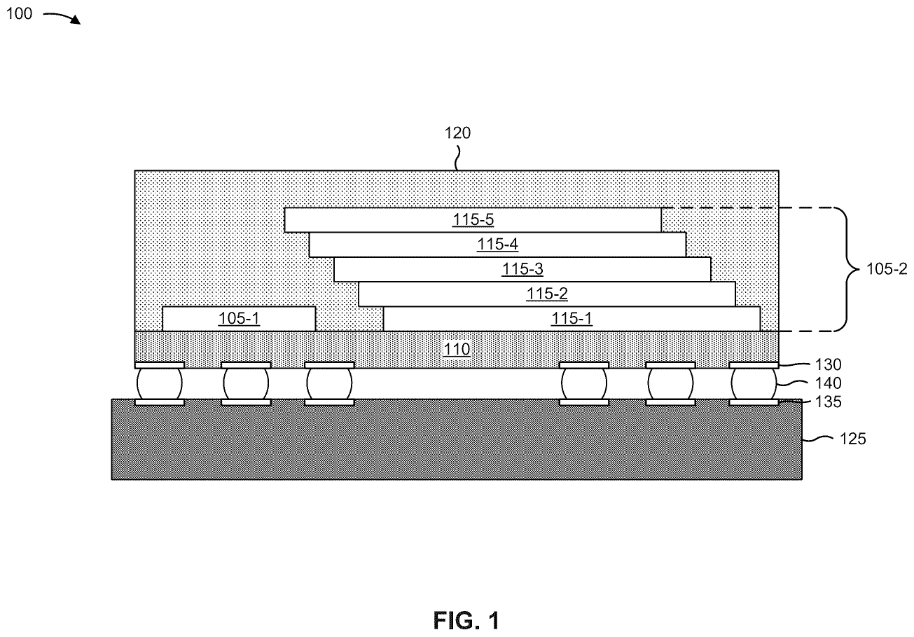

FIG. 1 is a diagram of an example apparatus 100 that may be manufactured using techniques described herein. The apparatus 100 may include any type of device or system that includes one or more integrated circuits 105. For example, the apparatus 100 may include a memory device, a flash memory device, a NAND memory device, a NOR memory device, a random access memory (RAM) device, a read-only memory (ROM) device, a dynamic RAM (DRAM) device, a static RAM (SRAM) device, a solid state drive (SSD), a microchip, and/or a system on a chip (SoC), among other examples. In some cases, the apparatus 100 may be referred to as a semiconductor package, an assembly, a semiconductor device assembly, or an integrated assembly.

As shown in FIG. 1, the apparatus 100 may include one or more integrated circuits 105, shown as a first integrated circuit 105-1 and a second integrated circuit 105-2, disposed on a substrate 110. An integrated circuit 105 may include any type of circuit, such as an analog circuit, a digital circuit, a radiofrequency (RF) circuit, a power supply, a power management circuit, an input-output (I/O) chip, an application-specific integrated circuit (ASIC), a field-programmable gate array (FPGA), and/or a memory device (e.g., a NAND memory device, a NOR memory device, a RAM device, or a ROM device). An integrated circuit 105 may be mounted on or otherwise disposed on a surface of the substrate 110. Although the apparatus 100 is shown as including two integrated circuits 105 as an example, the apparatus 100 may include a different number of integrated circuits 105.

In some implementations, an integrated circuit 105 may include a single semiconductor die 115 (sometimes called a die), as shown by the first integrated circuit 105-1. In some implementations, an integrated circuit 105 may include multiple semiconductor dies 115 (sometimes called dies), as shown by the second integrated circuit 105-2, which is shown as including five semiconductor dies 115-1 through 115-5.

As shown in FIG. 1, for an integrated circuit 105 that includes multiple dies 115, the dies 115 may be stacked on top of each other to reduce a footprint of the apparatus 100. In some implementations, a spacer may be present between dies 115 that are adjacent to one another in the stack to enable electrical separation and heat dissipation. The stacked dies 115 may include three-dimensional electrical interconnects, such as through-silicon vias (TSVs), to route electrical signals between dies 115. Although the integrated circuit 105-2 is shown as including five dies 115, an integrated circuit 105 may include a different number of dies 115 (e.g., at least two dies 115). A first die 115-1 (sometimes called a bottom die or a base die) may be disposed on the substrate 110, a second die 115-2 may be disposed on the first die 115-1, and so on. Although FIG. 1 shows the dies 115 stacked in a shingle stack (e.g., with die edges that are not aligned, which provides space for wire bonding near the edges of the dies 115), in some implementations, the dies 115 may be stacked in a different arrangement, such as a straight stack (e.g., with aligned die edges).

The apparatus 100 may include a casing 120 that protects internal components of the apparatus 100 (e.g., the integrated circuits 105) from damage and environmental elements (e.g., particles) that can lead to malfunction of the apparatus 100. The casing 120 may be a mold compound, a plastic (e.g., an epoxy plastic), a ceramic, or another type of material depending on the functional requirements for the apparatus 100.

In some implementations, the apparatus 100 may be included as part of a higher level system (e.g., a computer, a mobile phone, a network device, an SSD, a vehicle, or an Internet of Things device), such as by electrically connecting the apparatus 100 to a circuit board 125, such as a printed circuit board. For example, the substrate 110 may be disposed on the circuit board 125 such that electrical contacts 130 (e.g., bond pads) of the substrate 110 are electrically connected to electrical contacts 135 (e.g., bond pads) of the circuit board 125.

In some implementations, the substrate 110 may be mounted on the circuit board 125 using solder balls 140 (e.g., arranged in a ball grid array), which may be melted to form a physical and electrical connection between the substrate 110 and the circuit board 125. Additionally, or alternatively, the substrate 110 may be mounted on and/or electrically connected to the circuit board 125 using another type of connector, such as pins or leads. Similarly, an integrated circuit 105 may include electrical pads (e.g., bond pads) that are electrically connected to corresponding electrical pads (e.g., bond pads) of the substrate 110 using electrical bonding, such as wire bonding, bump bonding, or the like. The interconnections between an integrated circuit 105, the substrate 110, and the circuit board 125 enable the integrated circuit 105 to receive and transmit signals to other components of the apparatus 100 and/or the higher level system.

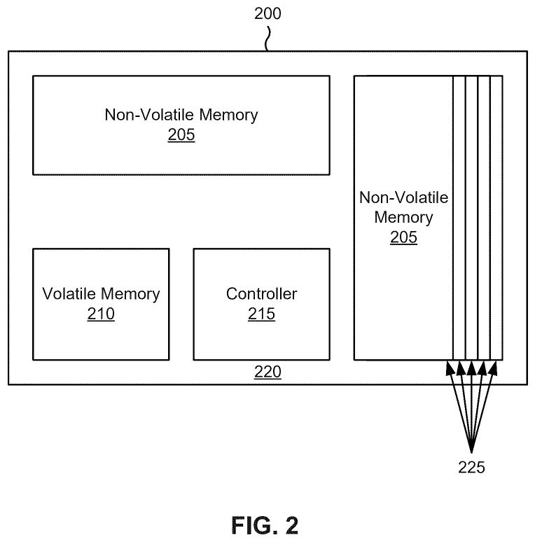

As described in greater detail in connection with FIG. 2 through FIG. 4M, the apparatus 100 may include one or more stacks of the semiconductor dies 115. Semiconductor dies 115 of the stack may be joined together without using DAF material, such as by using a direct bond. By using a direct bond to form the apparatus 100, the height of the apparatus 100 may be reduced, which may result in a reduced package profile. Furthermore, direct bonding may improve thermal conductivity between semiconductor dies, which may improve heat dissipation and thus improve thermal management of the semiconductor dies.

As indicated above, FIG. 1 is provided as an example. Other examples may differ from what is described with regard to FIG. 1.

FIG. 2 is a diagram of an example memory device 200 that may be manufactured using techniques described herein. The memory device 200 is an example of the apparatus 100 described above in connection with FIG. 1. The memory device 200 may be any electronic device configured to store data in memory. In some implementations, the memory device 200 may be an electronic device configured to store data persistently in non-volatile memory 205. For example, the memory device 200 may be a hard drive, an SSD, a flash memory device (e.g., a NAND flash memory device or a NOR flash memory device), a universal serial bus (USB) thumb drive, a memory card (e.g., a secure digital (SD) card), a secondary storage device, a non-volatile memory express (NVMe) device, and/or an embedded multimedia card (eMMC) device.

As shown, the memory device 200 may include non-volatile memory 205, volatile memory 210, and a controller 215. The components of the memory device 200 may be mounted on or otherwise disposed on a substrate 220. In some implementations, the non-volatile memory 205 includes a single die. Additionally, or alternatively, the non-volatile memory 205 may include multiple dies, such as stacked semiconductor dies 225 (e.g., in a straight stack, a shingle stack, or another type of stack), as described above in connection with FIG. 1.

The non-volatile memory 205 may be configured to maintain stored data after the memory device 200 is powered off. For example, the non-volatile memory 205 may include NAND memory or NOR memory. The volatile memory 210 may require power to maintain stored data and may lose stored data after the memory device 200 is powered off. For example, the volatile memory 210 may include one or more latches and/or RAM, such as DRAM and/or SRAM. As an example, the volatile memory 210 may cache data read from or to be written to non-volatile memory 205, and/or may cache instructions to be executed by the controller 215.

The controller 215 may be any device configured to communicate with the non-volatile memory 205, the volatile memory 210, and a host device (e.g., via a host interface of the memory device 200). For example, the controller 215 may include a memory controller, a system controller, an ASIC, an FPGA, a processor, a microcontroller, and/or one or more processing components. In some implementations, the memory device 200 may be included in a system that includes the host device. The host device may include one or more processors configured to execute instructions and store data in the non-volatile memory 205.

The controller 215 may be configured to control operations of the memory device 200, such as by executing one or more instructions (sometimes called commands). For example, the memory device 200 may store one or more instructions as firmware, and the controller 215 may execute those one or more instructions. Additionally, or alternatively, the controller 215 may receive one or more instructions from a host device via a host interface, and may execute those one or more instructions. For example, the controller 215 may transmit signals to and/or receive signals from the non-volatile memory 205 and/or the volatile memory 210 based on the one or more instructions, such as to transfer data to (e.g., write or program), to transfer data from (e.g., read), and/or to erase all or a portion of the non-volatile memory 205 (e.g., one or more memory cells, pages, sub-blocks, blocks, or planes of the non-volatile memory 205).

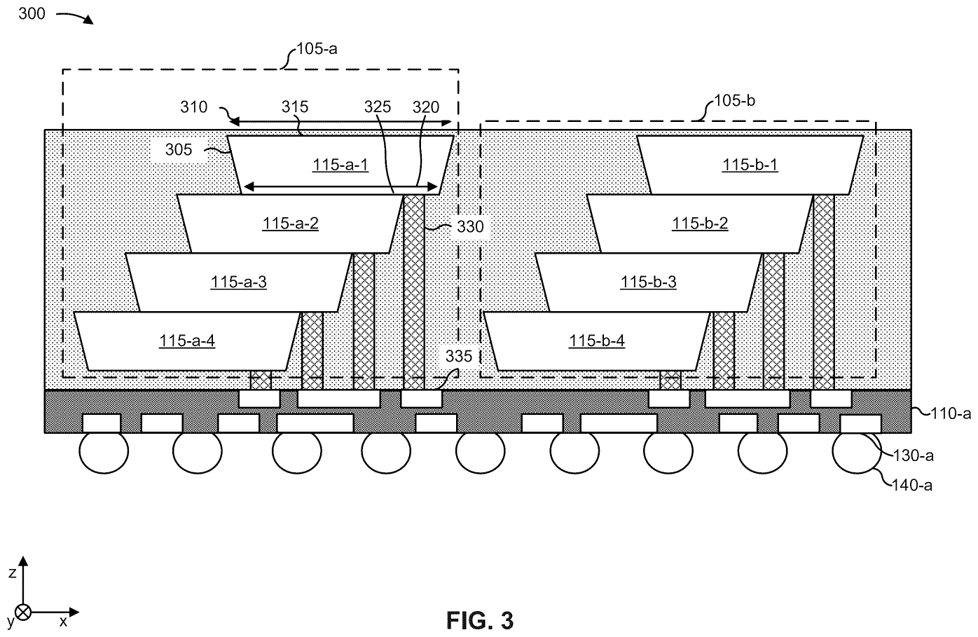

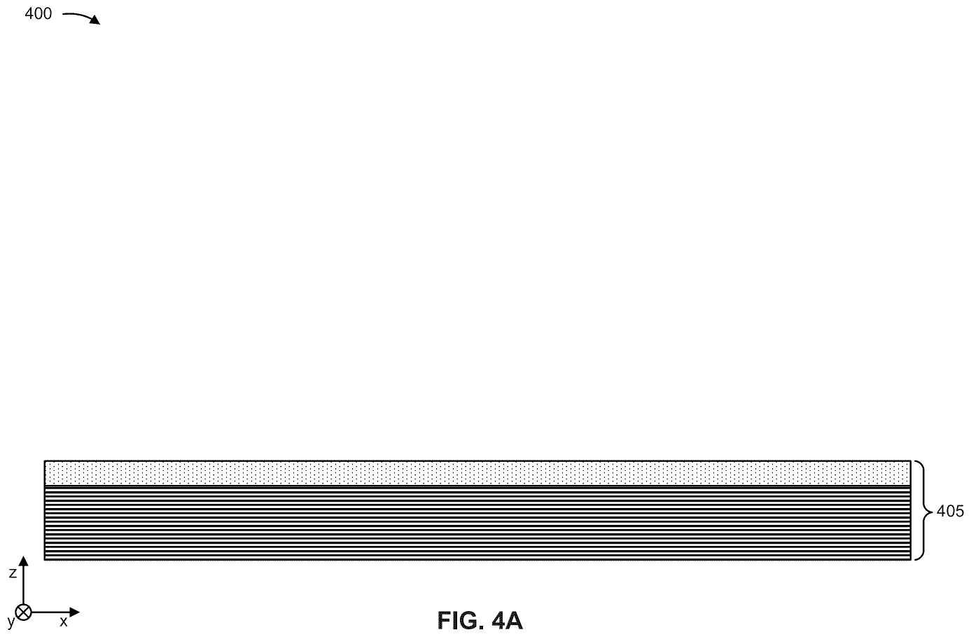

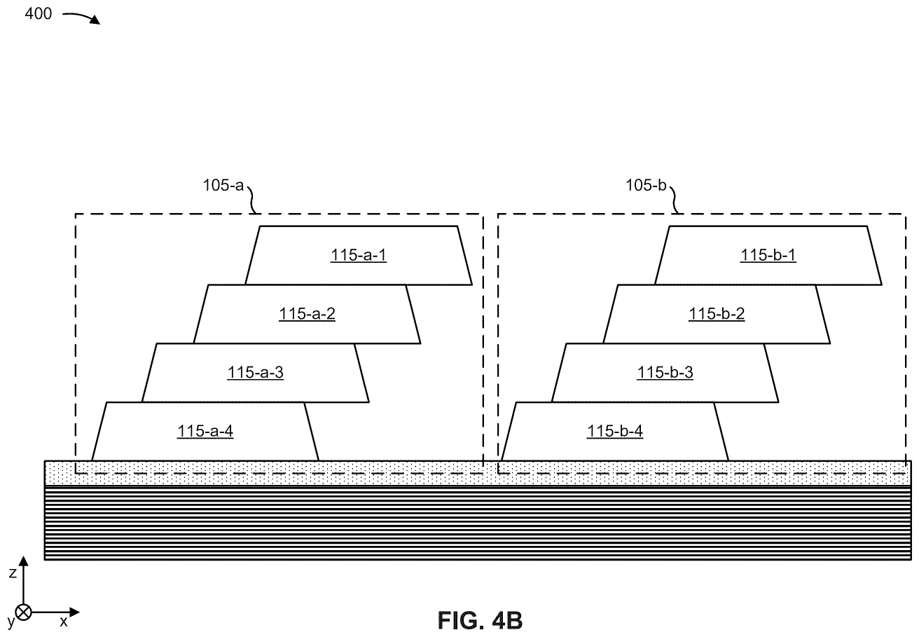

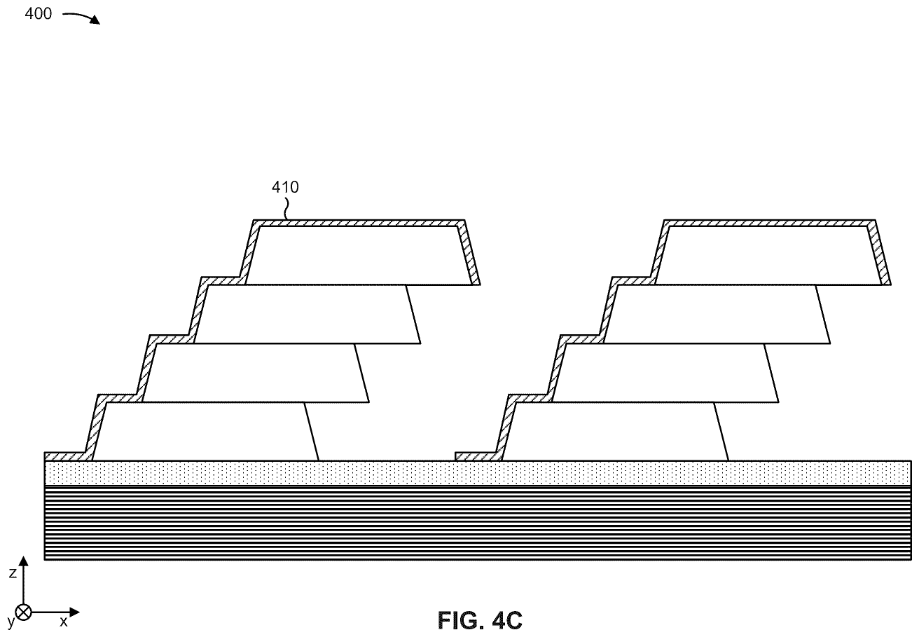

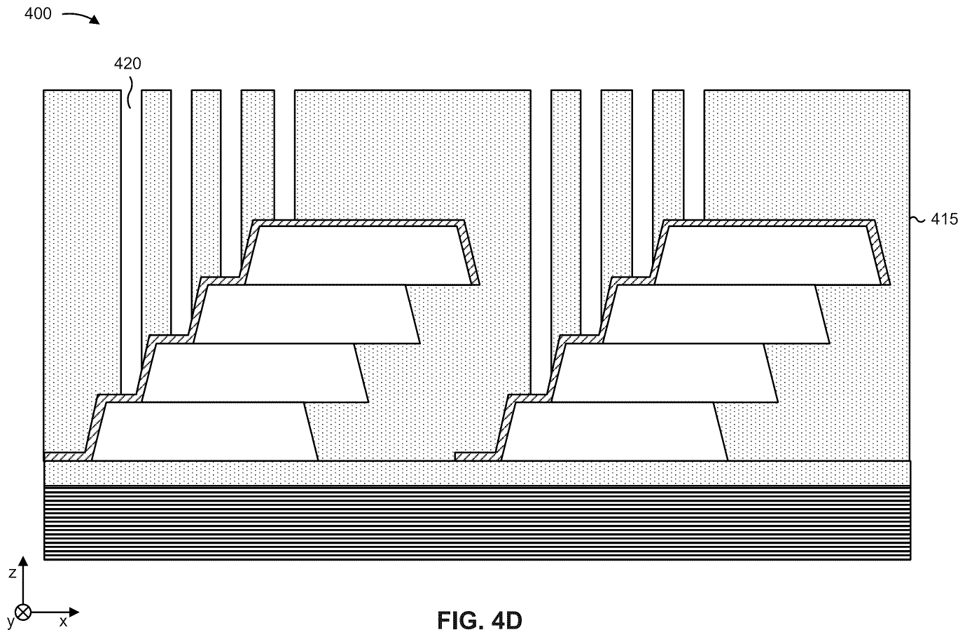

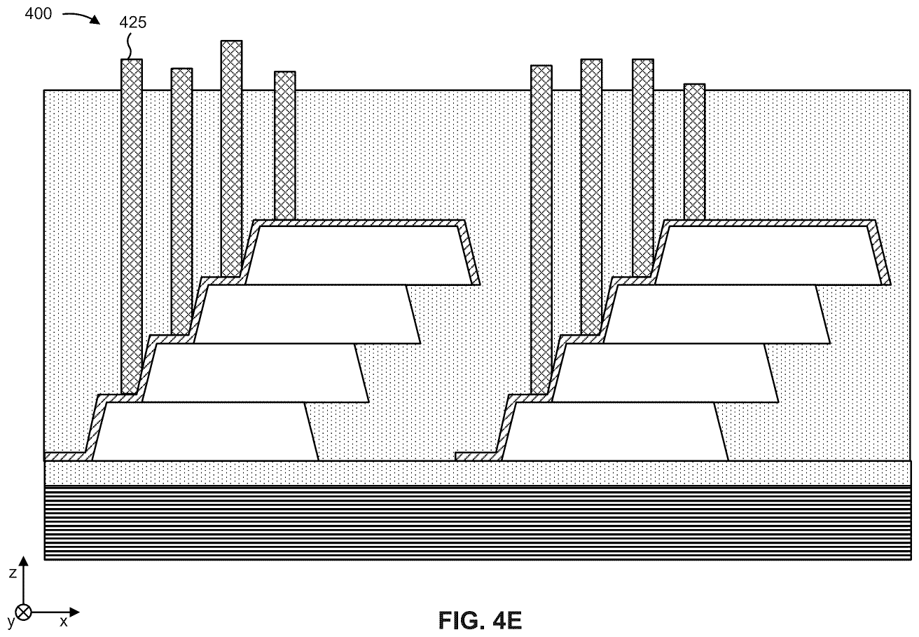

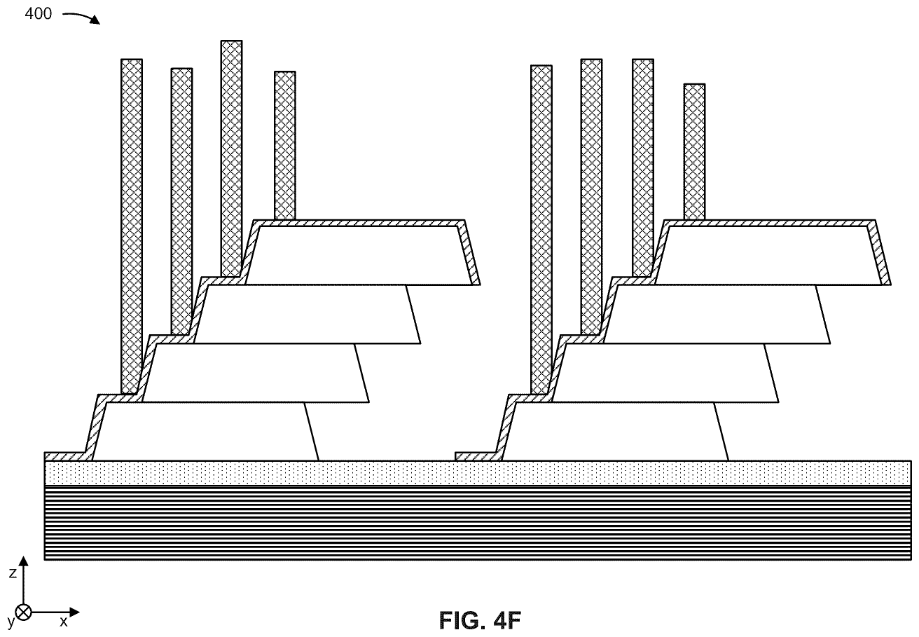

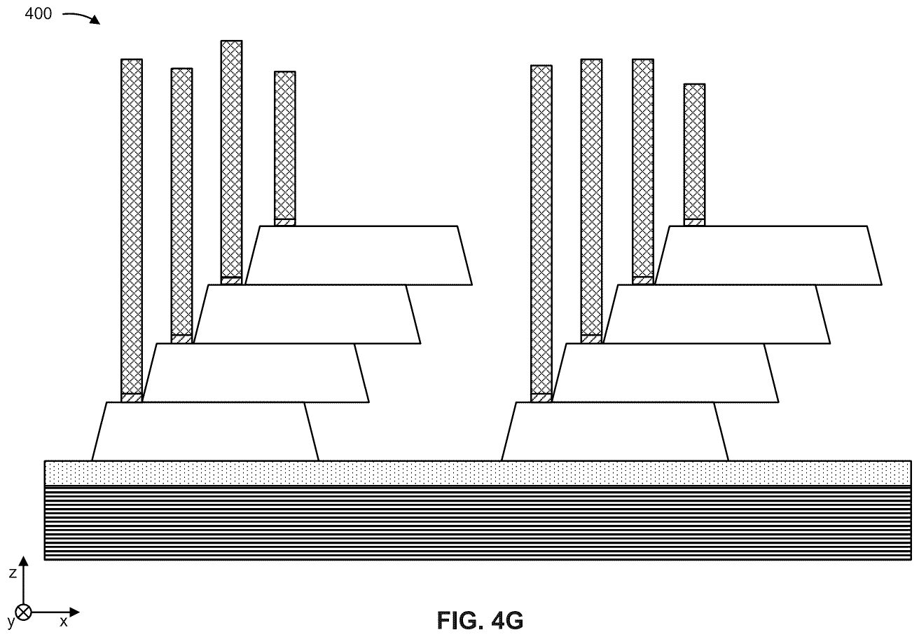

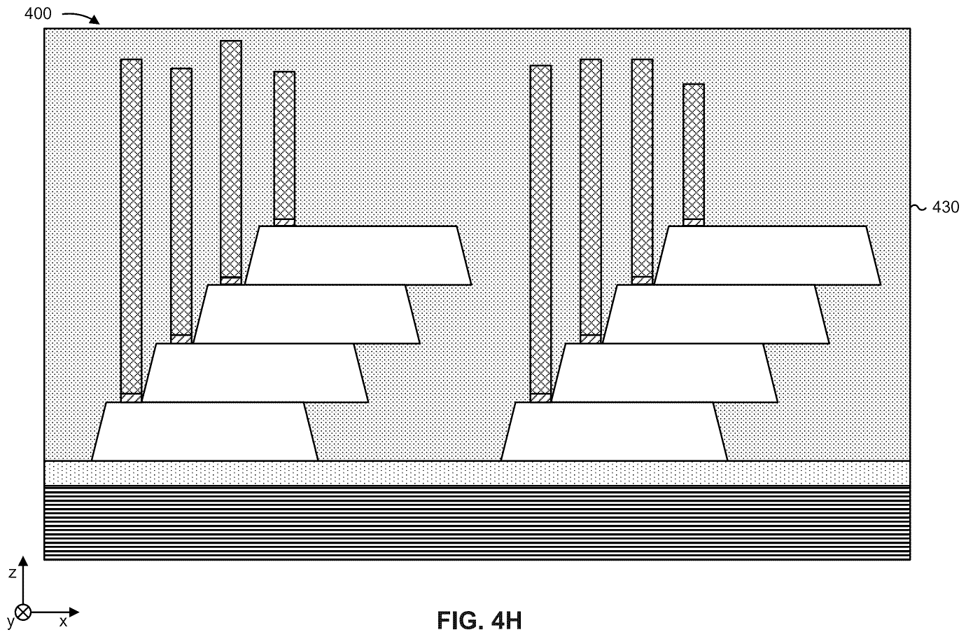

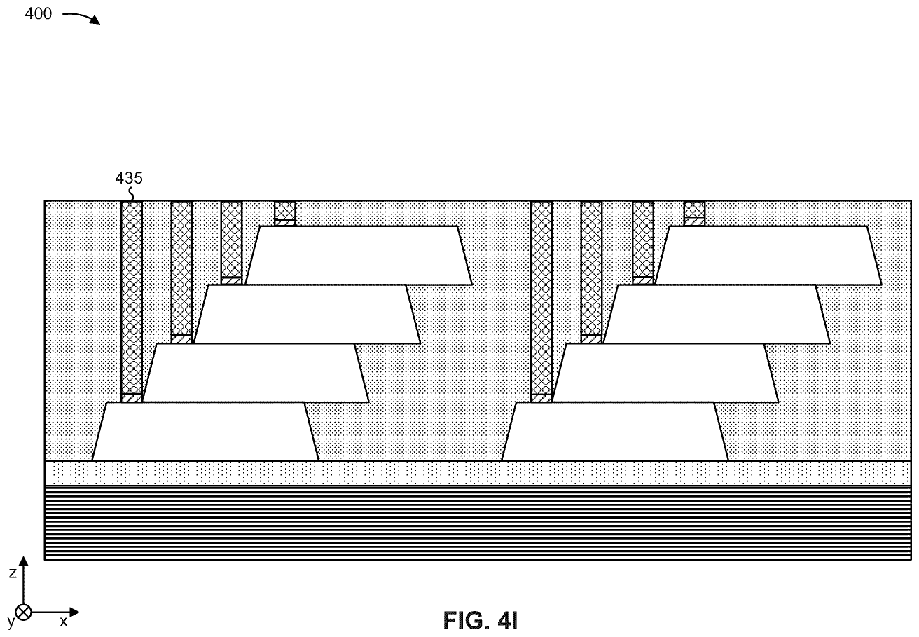

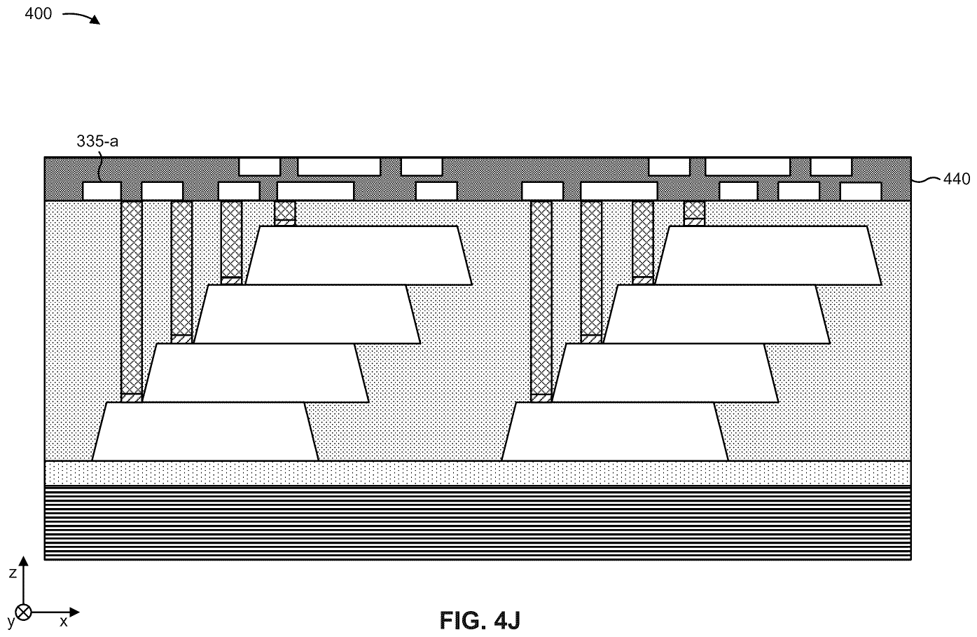

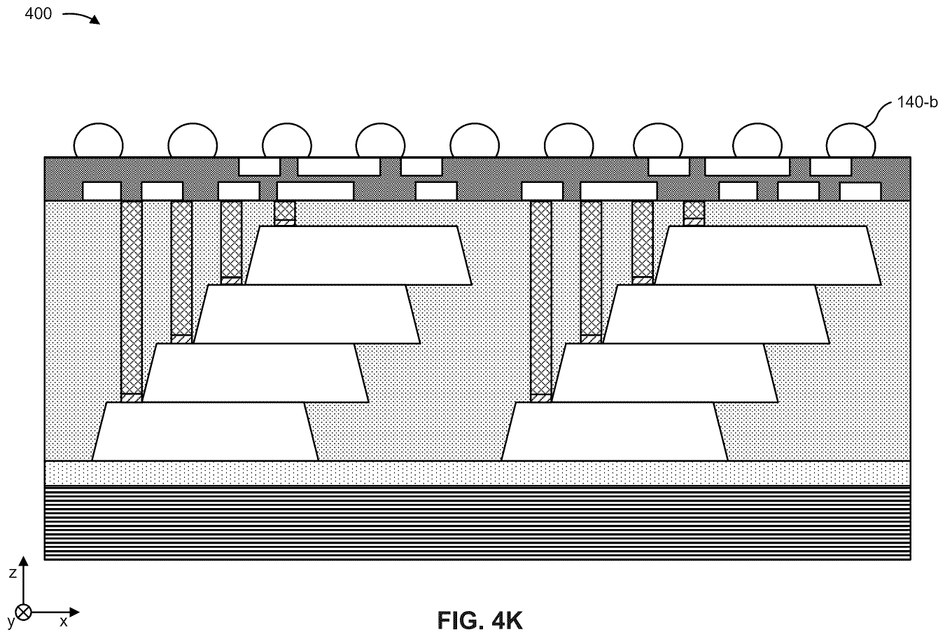

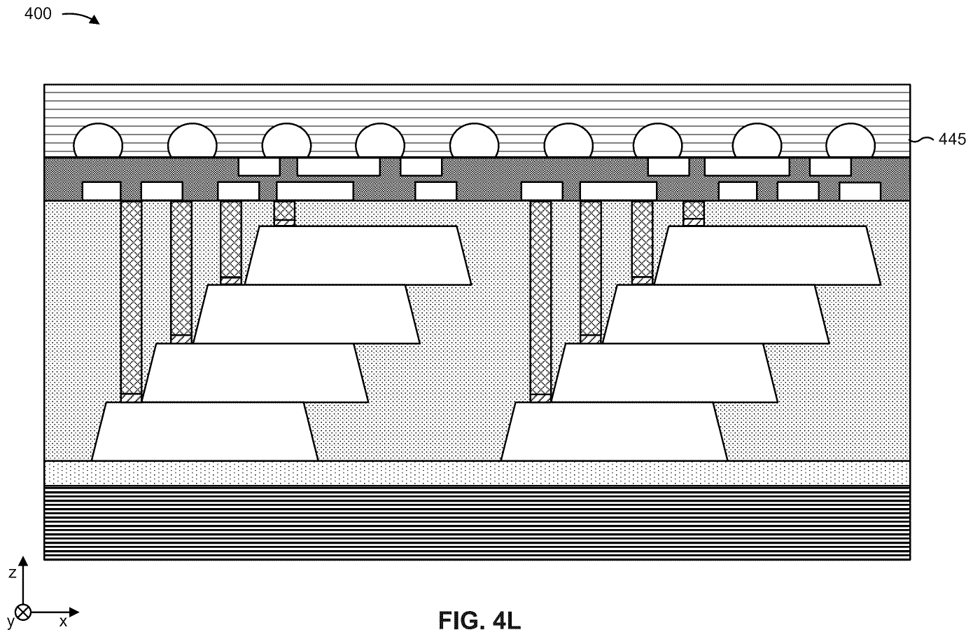

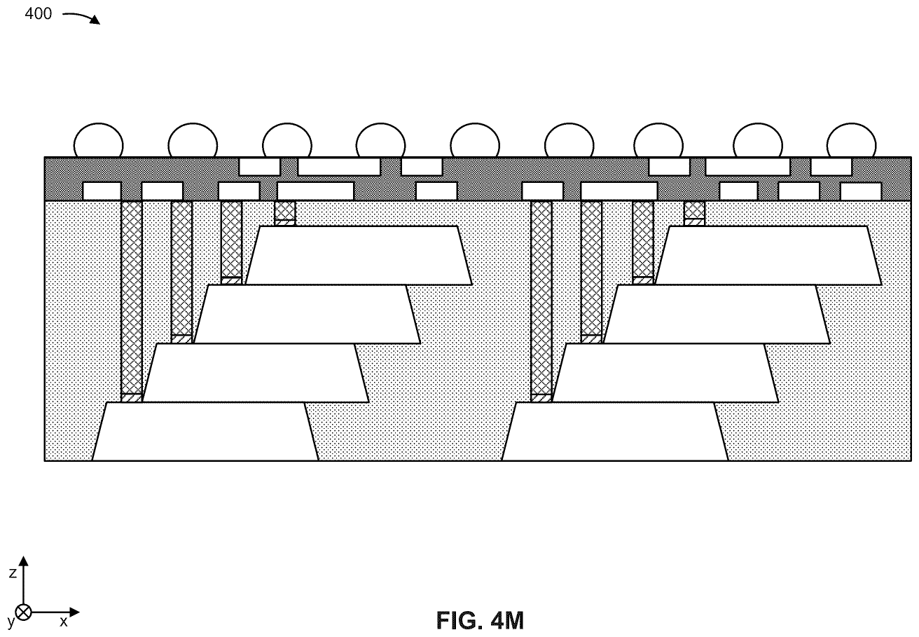

As described in greater detail in connection with FIG. 3 through FIG. 4M, the memory device 200 may include one or more stacks of the stacked semiconductor dies 225. Semiconductor dies of the stack may be joined together without using DAF material, such as by using a direct bond. By using a direct bond to form the memory device 200, the height of the memory device 200 may be reduced, which may result in a reduced package profile. Furthermore, direct bonding may improve thermal conductivity between semiconductor dies, which may improve heat dissipation and thus improve thermal management of the semiconductor dies.

As indicated above, FIG. 2 is provided as an example. Other examples may differ from what is described with regard to FIG. 2. The number and arrangement of components shown in FIG. 2 are provided as an example. In practice, there may be additional components, fewer components, different components, or differently arranged components than those shown in FIG. 2.

FIG. 3 is a diagram of an example apparatus 300 that supports semiconductor die stacks using direct bonds. The apparatus 300 may include one or more portions of the apparatus 100 of FIG. 1. Additionally, or alternatively, one or more aspects of the apparatus 300 may be included as part of the memory device 200 of FIG. 2. Each of the illustrated x-axis, y-axis, and z-axis is substantially perpendicular to the other two axes. In other words, the x-axis is substantially perpendicular to the y-axis and the z-axis, the y-axis is substantially perpendicular to the x-axis and the z-axis, and the z-axis is substantially perpendicular to the x-axis and the y-axis. In some cases, a single reference number is shown to refer to a surface, or fewer than all instances of a part may be labeled with all surfaces of that part. All instances of the part may include associated surfaces of that part despite not every surface being labeled.

The apparatus 300 may include one or more integrated circuits 105. An integrated circuit 105 may include a shingled stack of one or more semiconductor dies 115 extending above the substrate 110-a. For example, the apparatus 300 may include an integrated circuit 105-a having a stack of semiconductor dies 115-a-1 through 115-a-4 and an integrated circuit 105-b having a stack of semiconductor dies 115-b-1 through 115-b-4. A semiconductor die 115 may be an example of a memory device, such as a memory device having volatile memory (e.g., a DRAM device) and/or a memory device having non-volatile memory (e.g., a NAND device).

Semiconductor dies 115 of an integrated circuit may be disposed in a staggered stack, which may also be called a shingled stack, extending above the substrate 110-a in a vertical direction (e.g., the z-direction). For example, a first semiconductor die 115 may be offset from a second semiconductor die 115 directly beneath the first semiconductor die 115 in a horizontal direction (e.g., the x-direction). In some implementations, each semiconductor die 115 of a staggered stack may be offset in the same horizontal direction. Accordingly, a stack of semiconductor dies 115 may be progressively staggered in the horizontal direction.

A semiconductor die 115 may have one or more slanted sidewalls 305. A slanted sidewall 305 may extend in a vertical direction (e.g., the z-direction) and in a horizontal direction (e.g., the x-direction). Slanted sidewalls 305 of a semiconductor die 115 may be arranged such that the semiconductor die 115 has a trapezoidal shape. Said another way, slanted sidewalls 305 of a semiconductor die 115 may be oriented such that a width 310 in a direction parallel to the substrate 110-a (e.g., in the x-direction) of an upper surface 315 of the semiconductor die 115 may be greater than a width 320 in the direction parallel to the substrate 110-a (e.g., in the x-direction) of a lower surface 325 of the semiconductor die 115. Slanted sidewalls 305 may be formed as part of manufacturing a semiconductor die 115. For example, a singulation procedure may separate a semiconductor die 115 from a wafer in such a way as to form the slanted sidewalls 305. As described in greater detail in connection to FIGS. 4A through 4M, the slanted sidewalls 305 may enable the formation of a continuous layer of conductive material over an integrated circuit 105, which may assist in forming the one or more conductive pillars 330.

Semiconductor dies 115 of an integrated circuit 105 may be joined together using a direct bond (e.g., by directly bonding semiconductor dies 115). Directly bonding semiconductor dies 115 may include joining the semiconductor dies 115 without using a DAF material between the semiconductor dies 115, such as by forming a fusion bond between surfaces of semiconductor dies 115. For example, directly bonding a first semiconductor die 115 to a second semiconductor die 115 may include forming a fusion bond between an upper surface 315 of the first semiconductor die 115 to a lower surface 325 of the second semiconductor die 115. A fusion bond may be formed by first preparing the surfaces of the semiconductor dies 115 through cleaning and/or polishing. The cleaned and prepared surfaces may be brought into close proximity, which may result in weak adhesion through van der Waals forces and/or hydrogen bonds. The semiconductor dies 115 may be subjected to thermal annealing, which may facilitate atomic diffusion across the upper surface 315 and the lower surface 325. This diffusion may create strong covalent bonds between the surfaces. The overlapping surface region between coupled semiconductor dies 115 within a stack (a region that includes an upper surface 315 of a first semiconductor die 115 and a lower surface 325 of a second semiconductor die 115) may be a dielectric and/or an oxide surface region, which enables fusion bonding between the coupled semiconductor dies 115. On the other hand, the edges of semiconductor dies 115 (e.g., a portion of an upper surface 315 not in contact with a lower surface 325 and/or a portion of a lower surface 325 not in contact with an upper surface 32) may be configured to connect with respective conductive pillars 330.

By using a direct bond to form an integrated circuit 105, the mechanical stability of the integrated circuit 105 may be improved without including DAF material between semiconductor dies 115. Accordingly, the height of an integrated circuit 105 may be reduced, which may result in a reduced package profile. Furthermore, fusion bonding may improve thermal conductivity between semiconductor dies 115, which may improve heat dissipation and thus improve thermal management of the semiconductor dies 115.

The apparatus 300 may include one or more conductive pillars 330 electrically coupling the integrated circuits 105 to one or more contacts 335 of the substrate 110-a. The substrate 110-a may be an example of or may include a redistribution layer (RDL). An RDL may be a multilayer interconnect structure that redistributes electrical connections from an integrated circuit 105 via the one or more contacts 335 to a larger array of external contacts, such as one or more electrical contacts 130-a and/or one or more solder balls 140-a. The RDL may thus facilitate improved connections to other components or systems. An RDL may include one or more metal layers separated by insulating dielectric layers, with vias providing vertical electrical connections between the metal layers (e.g., vias between the one or more contacts 335 and the one or more contacts 130-a). The conductive pillars 330 may extend vertically (e.g., in the z-direction) from the substrate 110-a to respective lower surfaces 325 of semiconductor dies 115 to electrically couple each semiconductor die 115 with a respective one or more contacts 335 of the RDL.

As indicated above, FIG. 3 is provided as an example. Other examples may differ from what is described with respect to FIG. 3.

FIG. 4A through FIG. 4M are diagrammatic views showing formation of a portion of an apparatus (e.g., the apparatus 300) having semiconductor dies joined using direct bonds at example process stages of an example process 400 of forming the apparatus. The process 400 described below is an example, and other example processes may be used to form the apparatus, an integrated assembly that includes the apparatus, and/or one or more parts of the apparatus and/or the integrated assembly.

As shown in FIG. 4A, the process 400 may include preparing a carrier wafer 405. The carrier wafer 405 may serve as a temporary substrate for subsequent fabrication steps. For example, as shown in FIG. 4B, the process 400 may include forming the one or more integrated circuits 105 over the carrier wafer 405. An integrated circuit 105 may be formed by directly bonding one or more semiconductor dies 115 having slanted sidewalls to form a staggered stack of semiconductor dies 115.

As shown in FIG. 4C, the process 400 may include forming a layer 410 of a conductive material. For example, the process 400 may include depositing a continuous layer 410 of the conductive material to cover exposed portions of an integrated circuit 105. In some examples, the slanted sidewalls of the semiconductor dies 115 may assist in forming the layer 410. For example, the deposition process may be configured to deposit material on horizontal surfaces at a higher rate than vertical surfaces. Thus, substantially vertical sidewalls may not allow for adhesion to the conductive material. Therefore, slanted sidewalls may increase accessible surface area for deposition. This facilitates the formation of a continuous and uniform conductive layer 410 over the semiconductor dies 115, including areas that may otherwise be difficult to cover. The conductive layer 410 may be formed using techniques such as sputtering, chemical vapor deposition (CVD), and/or physical vapor deposition (PVD).

As shown in FIG. 4D, the process 400 may include forming a photoresist material 415 to cover the integrated circuits 105 and the layer 410. The process 400 may further include forming one or more cavities 420 within the photoresist material 415. For example, the process 400 may include removing one or more portions of the photoresist material 415 to expose one or more portions of the layer 410, such as by using an etching technique selective to the photoresist material 415 (e.g., photolithography). A selective etching technique may be a process configured to remove a first type of material, such as the photoresist material 415, without removing (or removing at a reduced rate) a second type of material, such as the conductive material of the layer 410. The one or more cavities 420 may serve as molds for subsequent processing steps.

For example, as shown in FIG. 4E, the process 400 may include forming one or more pillars 425 to fill the one or more cavities 420. To form the one or more pillars 425, the process 400 may include depositing a second conductive material within the one or more cavities 420, such as by using an electroplating process. The process 400 may include forming the one or more pillars 425 to be in contact with the exposed one or more portions of the layer 410. In some examples, the second conductive material may be the same material as the first conductive material of the layer 410. Alternatively, the second conductive layer may be different than the first conductive material. Following the formation of the one or more pillars 425, as shown in FIG. 4F, the process 400 may include removing one or more second portions of the photoresist material 415 (e.g., the residual photoresist material 415) to expose one or more second portions of the layer 410 and/or expose one or more sidewalls of the one or more pillars 425.

As shown in FIG. 4G, the process 400 may include removing the exposed one or more second portions of the layer 410. For example, the process 400 may include performing an etching procedure selective to the first conductive material of the layer 410, such as a wet etch configured to remove the first conductive material while maintaining the second conductive material. Thus, the one or more pillars 425 may remain intact while the exposed one or more second portions of the layer 410 may be removed.

As shown in FIG. 4H, the process 400 may include forming a molding material 430 to cover the integrated circuits 105 and/or the pillars 425. In some examples, forming the molding material 430 may provide mechanical stability to the one or more integrated circuits 105 during subsequent processing steps and/or operation of the apparatus 300. The molding material 430 may include relatively firm dielectric material, such as silicone, epoxy, and/or resin having various additives, among other examples. As shown in FIG. 4I, the process 400 may include removing a portion of the molding material 430 to expose one or more upper surfaces 435 of the one or more pillars 425. For example, the process 400 may include a planarization process to grind portions of the molding material 430 and/or portions of the one or more pillars 425. The planarization process may involve chemical-mechanical polishing (CMP) or other grinding techniques to achieve a suitably flat surface.

As shown in FIG. 4J, the process 400 may include forming a redistribution layer 440 over the integrated circuits 105 and the one or more pillars 425. The redistribution layer 440 may be an example of or may be included in the substrate 110-a. For example, the redistribution layer 440 may include one or more contacts 335-a that may be formed in contact with the respective upper surfaces 435 of the one or more pillars 425. As shown in FIG. 4K, the process 400 may include forming one or more solder balls 140-b on an upper surface of the redistribution layer 440.

In some examples, the process 400 may include removing the apparatus 300 from the carrier wafer 405. For example, as shown in FIG. 4L, the process 400 may include forming adhesive material 445, such as a backgrinding tape, to an upper surface of the redistribution layer 440 and/or the solder balls 140-b. As shown in FIG. 4M, the process 400 may include removing the carrier wafer 405, such as by grinding or other etching procedures. In some examples, after removing the carrier wafer 405, the process 400 may include additional processing steps, such as removing the adhesive material 445 and/or singulation procedures to separate the assembly formed by the process 400 into one or more integrated assemblies, such as one or more instances of the apparatus 300.

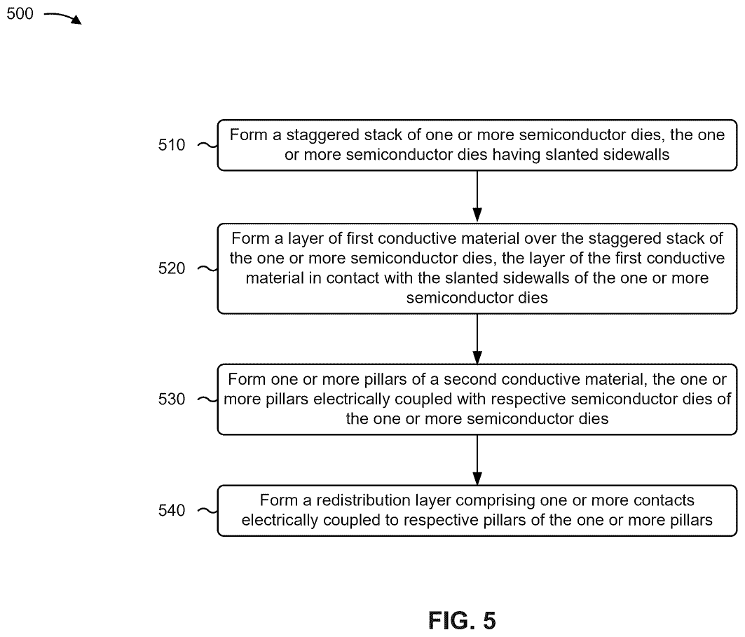

FIG. 5 is a flowchart of an example method 500 of forming an integrated assembly or memory device having semiconductor dies joined using direct bonds. In some implementations, one or more process blocks of FIG. 5 may be performed by various semiconductor manufacturing equipment.

As shown in FIG. 5, the method 500 may include forming a staggered stack of one or more semiconductor dies, the one or more semiconductor dies having slanted sidewalls (block 510). As further shown in FIG. 5, the method 500 may include forming a layer of first conductive material over the staggered stack of the one or more semiconductor dies, the layer of the first conductive material in contact with the slanted sidewalls of the one or more semiconductor dies (block 520). As further shown in FIG. 5, the method 500 may include forming one or more pillars of a second conductive material, the one or more pillars electrically coupled with respective semiconductor dies of the one or more semiconductor dies (block 530). As further shown in FIG. 5, the method 500 may include forming a redistribution layer comprising one or more contacts electrically coupled to respective pillars of the one or more pillars (block 540).

The method 500 may include additional aspects, such as any single aspect or any combination of aspects described below and/or in connection with one or more other methods described elsewhere herein.

In a first aspect, forming the staggered stack of the one or more semiconductor dies includes directing bonding a first semiconductor die of the one or more semiconductor dies to a second semiconductor die of the one or more semiconductor dies.

In a second aspect, alone or in combination with the first aspect, forming the staggered stack of the one or more semiconductor dies includes joining a first semiconductor die of the one or more semiconductor dies to a second semiconductor die of the one or more semiconductor dies using a process that does not include a DAF material.

In a third aspect, alone or in combination with one or more of the first and second aspects, forming the one or more pillars includes forming photoresist material to cover the staggered stack of semiconductor devices, forming one or more cavities in the photoresist material to expose portions of the layer of the first conductive material based on removing one or more portions of the photoresist material, and deposing the second conductive material in contact with the exposed one or more portions of the layer of the first conductive material.

In a fourth aspect, alone or in combination with one or more of the first through third aspects, the method 500 includes removing second portions of the photoresist material to expose one or more second portions of the layer of the first conductive material, and removing the exposed one or more second portions of the layer of the first conductive material.

In a fifth aspect, alone or in combination with one or more of the first through fourth aspects, the method 500 includes forming molding material to cover the staggered stack of the one or more semiconductor dies and to cover the one or more pillars, and exposing one or more respective upper surfaces of the one or more pillars based on planarizing the molding material, wherein the one or more contacts of the redistribution layer are in contact with the one or more respective upper surfaces of the one or more pillars.

Although FIG. 5 shows example blocks of the method 500, in some implementations, the method 500 may include additional blocks, fewer blocks, different blocks, or differently arranged blocks than those depicted in FIG. 5. In some implementations, the method 500 may include forming the integrated circuits 105 by directly bonding one or more semiconductor dies 115, an integrated assembly that includes the integrated circuits 105, any part described herein of the integrated circuits 105, and/or any part described herein of an integrated assembly that includes the integrated circuits 105. For example, the method 500 may include forming one or more of the slanted sidewalls 305, upper surfaces 315, lower surfaces 325, and/or conductive pillars 330.

The following provides an overview of some Aspects of the present disclosure:

Aspect 1: An integrated assembly, including: a substrate; a stack of one or more semiconductor dies, the one or more semiconductor dies including a first semiconductor die directly bonded to a second semiconductor die; and one or more conductive pillars that electrically couple respective semiconductor dies of the one or more semiconductor dies with the substrate.

Aspect 2: The integrated assembly of Aspect 1, wherein the first semiconductor die includes an upper surface directly bonded to a lower surface of the second semiconductor die.

Aspect 3: The integrated assembly of Aspect 2, wherein the one or more conductive pillars include a first conductive pillar and a second conductive pillar, the first conductive pillar electrically coupled to a second lower surface of the first semiconductor die and the second conductive pillar electrically coupled to the lower surface of the second semiconductor die.

Aspect 4: The integrated assembly of any of Aspects 1-3, wherein the first semiconductor die is directly bonded to the second semiconductor die using a fusion bond.

Aspect 5: The integrated assembly of any of Aspects 1-4, wherein the first semiconductor die includes a lower surface having a first width in a direction parallel to the substrate and the first semiconductor die includes an upper surface having a second width in the direction greater than the first width.

Aspect 6: The integrated assembly of any of Aspects 1-5, wherein the stack of the one or more semiconductor dies does not include a die attach film (DAF) between the first semiconductor die and the second semiconductor die.

Aspect 7: The integrated assembly of any of Aspects 1-6, wherein the stack of the one or more semiconductor dies is progressively staggered in a direction parallel to the substrate.

Aspect 8: The integrated assembly of any of Aspects 1-7, wherein the one or more conductive pillars extend vertically from the substrate to respective semiconductor dies of the one or more semiconductor dies.

Aspect 9: The integrated assembly of any of Aspects 1-8, wherein the substrate includes: a redistribution layer including one or more contacts in contact with respective conductive pillars of the one or more conductive pillars.

Aspect 10: An integrated assembly, including: a substrate; a shingled stack of one or more memory devices, the one or more memory devices having slanted sidewalls; and one or more conductive pillars that electrically couple respective memory devices of the one or more memory devices with the substrate.

Aspect 11: The integrated assembly of Aspect 10, wherein the one or more memory devices includes a first memory device and a second memory device, the first memory device having an upper surface directly bonded to a lower surface of the second memory device.

Aspect 12: The integrated assembly of Aspect 11, wherein the one or more conductive pillars include a first conductive pillar and a second conductive pillar, the first conductive pillar electrically coupled to a second lower surface of the first memory device and the second conductive pillar electrically coupled to the lower surface of the second memory device.

Aspect 13: The integrated assembly of Aspect 11, wherein the first memory device is directly bonded to the second memory device using a fusion bond.

Aspect 14: The integrated assembly of Aspect 11, wherein the shingled stack of the one or more memory devices does not include a die attach film (DAF) between the first memory device and the second memory device.

Aspect 15: The integrated assembly of any of Aspects 10-14, wherein the shingled stack of the one or more memory devices is progressively staggered in a direction parallel to the substrate.

Aspect 16: The integrated assembly of any of Aspects 10-15, wherein the one or more conductive pillars extend vertically from the substrate to respective memory devices of the one or more memory devices.

Aspect 17: The integrated assembly of any of Aspects 10-16, wherein the one or more memory devices include a dynamic random-access memory (DRAM) device.

Aspect 18: A method, including: forming a staggered stack of one or more semiconductor dies, the one or more semiconductor dies having slanted sidewalls; forming a layer of first conductive material over the staggered stack of the one or more semiconductor dies, the layer of the first conductive material in contact with the slanted sidewalls of the one or more semiconductor dies; forming one or more pillars of a second conductive material, the one or more pillars electrically coupled with respective semiconductor dies of the one or more semiconductor dies; and forming a redistribution layer including one or more contacts electrically coupled to respective pillars of the one or more pillars.

Aspect 19: The method of Aspect 18, wherein forming the staggered stack of the one or more semiconductor dies includes: direct bonding a first semiconductor die of the one or more semiconductor dies to a second semiconductor die of the one or more semiconductor dies.

Aspect 20: The method of any of Aspects 18-19, wherein forming the staggered stack of the one or more semiconductor dies includes: joining a first semiconductor die of the one or more semiconductor dies to a second semiconductor die of the one or more semiconductor dies using a process that does not include a die attach film (DAF) material.

Aspect 21: The method of any of Aspects 18-20, wherein forming the one or more pillars includes: forming photoresist material to cover the staggered stack of semiconductor devices; forming one or more cavities in the photoresist material to expose portions of the layer of the first conductive material based on removing one or more portions of the photoresist material; and deposing the second conductive material in contact with the exposed one or more portions of the layer of the first conductive material.

Aspect 22: The method of Aspect 21, further including: removing second portions of the photoresist material to expose one or more second portions of the layer of the first conductive material; and removing the exposed one or more second portions of the layer of the first conductive material.

Aspect 23: The method of any of Aspects 18-22, further including: forming molding material to cover the staggered stack of the one or more semiconductor dies and to cover the one or more pillars; and exposing one or more respective upper surfaces of the one or more pillars based on planarizing the molding material, wherein the one or more contacts of the redistribution layer are in contact with the one or more respective upper surfaces of the one or more pillars.

In some implementations, an integrated assembly includes a substrate; a stack of one or more semiconductor dies, the one or more semiconductor dies comprising a first semiconductor die directly bonded to a second semiconductor die; and one or more conductive pillars that electrically couple respective semiconductor dies of the one or more semiconductor dies with the substrate.

In some implementations, an integrated assembly includes a substrate; a shingled stack of one or more memory devices, the one or more memory devices having slanted sidewalls; and one or more conductive pillars that electrically couple respective memory devices of the one or more memory devices with the substrate.

In some implementations, a method includes forming a staggered stack of one or more semiconductor dies, the one or more semiconductor dies having slanted sidewalls; forming a layer of first conductive material over the staggered stack of the one or more semiconductor dies, the layer of the first conductive material in contact with the slanted sidewalls of the one or more semiconductor dies; forming one or more pillars of a second conductive material, the one or more pillars electrically coupled with respective semiconductor dies of the one or more semiconductor dies; and forming a redistribution layer comprising one or more contacts electrically coupled to respective pillars of the one or more pillars.

The foregoing disclosure provides illustration and description but is not intended to be exhaustive or to limit the implementations to the precise forms disclosed. Modifications and variations may be made in light of the above disclosure or may be acquired from practice of the implementations described herein.

The orientations of the various elements in the figures are shown as examples, and the illustrated examples may be rotated relative to the depicted orientations. The descriptions provided herein, and the claims that follow, pertain to any structures that have the described relationships between various features, regardless of whether the structures are in the particular orientation of the drawings, or are rotated relative to such orientation. Similarly, spatially relative terms, such as “below,” “beneath,” “lower,” “above,” “upper,” “middle,” “left,” and “right,” are used herein for ease of description to describe one element's relationship to one or more other elements as illustrated in the figures. The spatially relative terms are intended to encompass different orientations of the element, structure, and/or assembly in use or operation in addition to the orientations depicted in the figures. A structure and/or assembly may be otherwise oriented (rotated 90 degrees or at other orientations), and the spatially relative descriptors used herein may be interpreted accordingly. Furthermore, the cross-sectional views in the figures only show features within the planes of the cross-sections, and do not show materials behind the planes of the cross-sections, unless indicated otherwise, in order to simplify the drawings.

As used herein, the terms “substantially” and “approximately” mean “within reasonable tolerances of manufacturing and measurement.” All ranges described herein are inclusive of numbers at the ends of those ranges, unless specifically indicated otherwise.

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. An integrated assembly, comprising:
a substrate;
a stack of one or more semiconductor dies, the one or more semiconductor dies comprising a first semiconductor die directly bonded to a second semiconductor die; and
one or more conductive pillars that electrically couple respective semiconductor dies of the one or more semiconductor dies with the substrate.

2. The integrated assembly of claim 1, wherein the first semiconductor die comprises an upper surface directly bonded to a lower surface of the second semiconductor die.

3. The integrated assembly of claim 2, wherein the one or more conductive pillars comprise a first conductive pillar and a second conductive pillar, the first conductive pillar electrically coupled to a second lower surface of the first semiconductor die and the second conductive pillar electrically coupled to the lower surface of the second semiconductor die.

4. The integrated assembly of claim 1, wherein the first semiconductor die is directly bonded to the second semiconductor die using a fusion bond.

5. The integrated assembly of claim 1, wherein the first semiconductor die includes a lower surface having a first width in a direction parallel to the substrate and the first semiconductor die includes an upper surface having a second width in the direction greater than the first width.

6. The integrated assembly of claim 1, wherein the stack of the one or more semiconductor dies does not include a die attach film (DAF) between the first semiconductor die and the second semiconductor die.

7. The integrated assembly of claim 1, wherein the stack of the one or more semiconductor dies is progressively staggered in a direction parallel to the substrate.

8. The integrated assembly of claim 1, wherein the one or more conductive pillars extend vertically from the substrate to respective semiconductor dies of the one or more semiconductor dies.

9. The integrated assembly of claim 1, wherein the substrate comprises:
a redistribution layer comprising one or more contacts in contact with respective conductive pillars of the one or more conductive pillars.

10. An integrated assembly, comprising:
a substrate;
a shingled stack of one or more memory devices, the one or more memory devices having slanted sidewalls; and
one or more conductive pillars that electrically couple respective memory devices of the one or more memory devices with the substrate.

11. The integrated assembly of claim 10, wherein the one or more memory devices comprises a first memory device and a second memory device, the first memory device having an upper surface directly bonded to a lower surface of the second memory device.

12. The integrated assembly of claim 11, wherein the one or more conductive pillars comprise a first conductive pillar and a second conductive pillar, the first conductive pillar electrically coupled to a second lower surface of the first memory device and the second conductive pillar electrically coupled to the lower surface of the second memory device.

13. The integrated assembly of claim 11, wherein the first memory device is directly bonded to the second memory device using a fusion bond.

14. The integrated assembly of claim 11, wherein the shingled stack of the one or more memory devices does not include a die attach film (DAF) between the first memory device and the second memory device.

15. The integrated assembly of claim 10, wherein the shingled stack of the one or more memory devices is progressively staggered in a direction parallel to the substrate.

16. The integrated assembly of claim 10, wherein the one or more conductive pillars extend vertically from the substrate to respective memory devices of the one or more memory devices.

17. The integrated assembly of claim 10, wherein the one or more memory devices include a dynamic random-access memory (DRAM) device.

18. A method, comprising:
forming a staggered stack of one or more semiconductor dies, the one or more semiconductor dies having slanted sidewalls;
forming a layer of first conductive material over the staggered stack of the one or more semiconductor dies, the layer of the first conductive material in contact with the slanted sidewalls of the one or more semiconductor dies;
forming one or more pillars of a second conductive material, the one or more pillars electrically coupled with respective semiconductor dies of the one or more semiconductor dies; and
forming a redistribution layer comprising one or more contacts electrically coupled to respective pillars of the one or more pillars.

19. The method of claim 18, wherein forming the staggered stack of the one or more semiconductor dies comprises:
direct bonding a first semiconductor die of the one or more semiconductor dies to a second semiconductor die of the one or more semiconductor dies.

20. The method of claim 18, wherein forming the staggered stack of the one or more semiconductor dies comprises:
joining a first semiconductor die of the one or more semiconductor dies to a second semiconductor die of the one or more semiconductor dies using a process that does not include a die attach film (DAF) material.

21. The method of claim 18, wherein forming the one or more pillars comprises:
forming photoresist material to cover the staggered stack of semiconductor devices;
forming one or more cavities in the photoresist material to expose portions of the layer of the first conductive material based on removing one or more portions of the photoresist material; and
deposing the second conductive material in contact with the exposed one or more portions of the layer of the first conductive material.

22. The method of claim 21, further comprising:
removing second portions of the photoresist material to expose one or more second portions of the layer of the first conductive material; and
removing the exposed one or more second portions of the layer of the first conductive material.

23. The method of claim 18, further comprising:
forming molding material to cover the staggered stack of the one or more semiconductor dies and to cover the one or more pillars; and
exposing one or more respective upper surfaces of the one or more pillars based on planarizing the molding material, wherein the one or more contacts of the redistribution layer are in contact with the one or more respective upper surfaces of the one or more pillars.
